(19) United States
(12) Patent Application Publication
(10) Pub. No.: US 2012/0166121 A1
(43) Pub. Date: Jun. 28, 2012

(54) APPARATUS FOR DETECTING REAL TIME CLOCK FREQUENCY OFFSET AND METHOD THEREOF

(75) Inventors: Wan Cheol YANG, Gyunggi-do (KR); Kyung Uk KIM, Seoul (KR)

(73) Assignee: SAMSUNG ELECTRO-MECHANICS CO., LTD., Gyunggi-do (KR)

(21) Appl. No.: 13/074,500

(22) Filed: Mar. 29, 2011

(30) Foreign Application Priority Data
Dec. 24, 2010 (KR) 1020100134519

(51) Int. Cl. G01R 29/02; G06F 19/00; G01R 23/02

(52) U.S. Cl. 702/79; 324/76.39

(57) ABSTRACT

An apparatus for detecting a real time clock frequency offset includes: an overlap detecting unit detecting an overlap signal having overlap information of a predetermined reference clock and a predetermined real time clock; an envelope signal creating unit creating an envelope signal having envelope information of the overlap signal; and a frequency counter unit calculating a frequency of the envelope signal that is a frequency offset of the real time clock, by using a first clock number created by counting the reference clock for one period of the envelope signal and a frequency of the reference clock.

### CROSS-REFERENCE TO RELATED APPLICATIONS

This application claims the priority of Korean Patent Application No. 10-2010-0134519 filed on Dec. 24, 2010, in the Korean Intellectual Property Office, the disclosure of which is incorporated herein by reference.

### BACKGROUND OF THE INVENTION

1. Field of the Invention

The present invention relates to an apparatus for detecting a real time clock frequency offset and a method thereof.

2. Description of the Related Art

In general, a crystal oscillator can be used in systems or apparatuses using a real time clock to create the real time clock. The crystal oscillator has an initial frequency offset value, depending on the quality thereof, which may cause an error in the created real time clock. Therefore, it is required to find out the real time clock frequency offset, as the error in the real time clock needs to be corrected in order to increase the accuracy thereof.

A frequency error has previously been manually determined by comparing a reference signal with a real time clock that is created by a reference signal generator and a frequency comparator or the like, to detect a frequency offset of a real time clock in the related art.

However, detecting the real time clock frequency offset according to the related art requires relatively expensive equipment, such as the frequency comparator or the like, to acquire a real time clock frequency offset value, and is performed by hand, such that an error is likely to occur and the automation thereof is difficult to be implemented.

### SUMMARY OF THE INVENTION

An object of the present invention is to provide an apparatus automatically detecting a real time clock frequency offset, without the use of expensive equipment, such as a frequency comparator or the like, and a method thereof.

The aspect of the present invention provides an apparatus for detecting a real time clock frequency offset, the apparatus including: an overlap detecting unit detecting an overlap signal having overlap information of a predetermined reference clock and a predetermined real time clock; an envelope signal creating unit creating an envelope signal having envelope information of the overlap signal; and a frequency counter unit calculating a frequency of the envelope signal that is a frequency offset of the real time clock, by using a first clock number created by counting the reference clock for one period of the envelope signal and a frequency of the reference clock.

Further, the apparatus may further include: a first counter creating a second clock number by counting the reference clock for a predetermined time; a second counter creating a third clock number by counting the real time clock for a predetermined time; and an offset sign determining unit determining a sign of the frequency offset of the real time clock by comparing the second clock number with the third clock number.

Further, the frequency counter unit may include: a rising edge detector detecting rising edges of the envelope signal; a third counter creating the first clock number by counting the reference clock between one rising edge and the next rising edge of the envelope signal; and a calculator calculating the frequency of the envelope signal that is the frequency offset of the real time clock, by using the first clock number and the frequency of the reference clock.

Further, the third counter may receive the rising edges through a reset terminal thereof.

Further, the frequency offset of the real time clock may be calculated by the following formula:

$$Δ f = \frac{1}{( N / f )} ,$$

where Δf is the frequency offset of the real time clock, N is the first clock number, and f is the frequency of the reference clock.

Further, the overlap detecting unit may include an AND gate performing an AND-operation on the reference clock and the real time clock.

Another aspect of the present invention provides a method for detecting a real time clock frequency offset, the method includes: detecting an overlap signal having overlap information of a predetermined reference clock and a predetermined real time clock; creating an envelope signal having envelope information of the overlap signal; and calculating a frequency of the envelope signal that is a frequency offset of the real time clock, by using a first clock number counting the reference clock for one period of the envelope signal and a frequency of the reference clock.

Further, the method may further include: counting the reference clock and the real time clock for a predetermined time; and determining a sign of the frequency offset of the real time clock by comparing a second clock number created by counting the reference clock with a third clock number created by counting the real time clock.

Further, the calculating of the frequency of the envelope signal may include: detecting rising edges of the envelope signal; creating the first clock number by counting the reference clock between one rising edge and the next rising edge of the envelope signal; and calculating the frequency of the envelope signal that is the frequency offset of the real time clock, by using the first clock number and the frequency of the reference clock.

Further, the creating of the first clock number may include resetting the counting of the reference clock at the rising edge.

Further, the frequency offset of the real time clock may be calculated by the following formula:

$$Δ f = \frac{1}{( N / f )} ,$$

where Δf is the frequency offset of the real time clock, N is the first clock number, and f is the frequency of the reference clock.

Further, the detecting of the overlap signal may include performing an AND-operation on the reference clock and the real time clock.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a configuration diagram illustrating an apparatus for detecting a real time clock frequency offset according to an embodiment of the present invention.

FIG. 2 is a detailed diagram of FIG. 1.

FIG. 3 is a timing chart illustrating signals and operations of respective units in the apparatus for detecting a real time clock frequency offset according to an embodiment of the present invention.

FIG. 4 is a flowchart illustrating respective processes of a method for detecting a real time clock frequency offset according to an embodiment of the present invention.

### DETAILED DESCRIPTION OF THE PREFERRED EMBODIMENT

Hereinafter, embodiments of the present invention will be described with reference to the accompanying drawings.

The present invention is not limited to the embodiments described herein and the embodiments of the present invention are provided to help understand the spirit of the present invention. The components having substantially the same configurations and functions are designated by the same reference numerals in the accompanying drawing of the present invention.

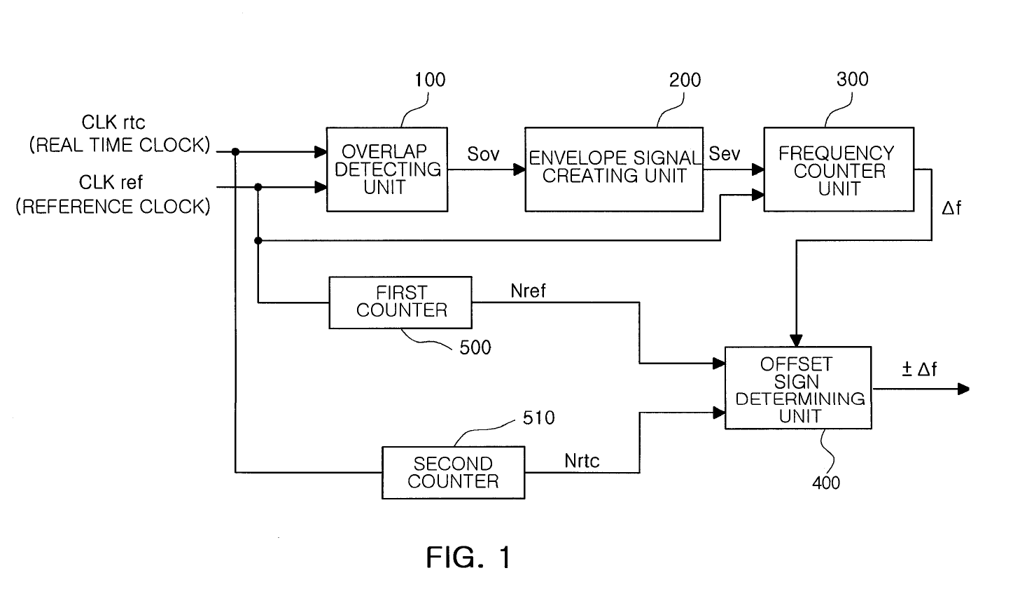

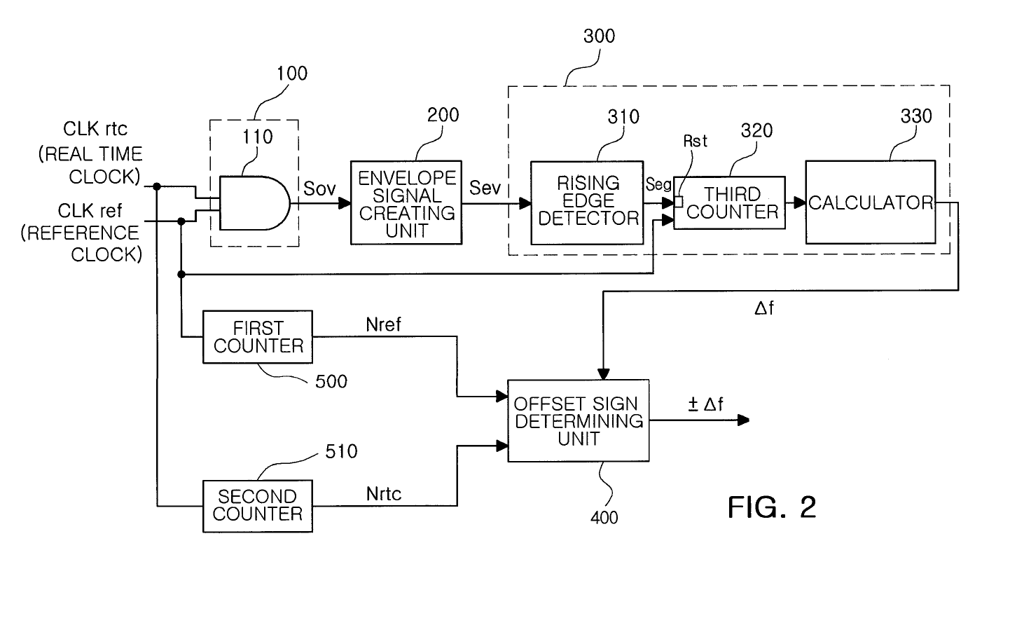

FIGS. 1 and 2 are, respectively, a configuration diagram and a detailed diagram of an apparatus for detecting a real time clock frequency offset according to an embodiment of the present invention.

Referring to FIG. 1, an apparatus for detecting a real time clock frequency offset according to an embodiment of the present invention may be supplied with a reference clock CLKref from an external signal generator.

An overlap detecting unit 100 may receive the reference clock CLKref that may be inputted from the outside and a real time clock CLKrtc created by a crystal oscillator and overlap the two clocks, thereby creating an overlap signal Sov having the overlap information of the two clocks. In detail, referring to FIG. 2, the overlap detecting unit 100 may include an AND gate that performs an AND-operation on the reference clock CLKref and the real time clock CLKrtc.

An envelope signal creating unit 200 may receive the overlap signal Sov created by the overlap detecting unit 100 and detect an envelope of the overlap signal Sov to create an envelope signal. In detail, since the overlap signal Sov has periodicity, an envelope signal Sev corresponding to the detected envelope also has periodicity.

A frequency counter unit 300 may calculate the frequency of the envelope signal Sev by receiving the reference clock CLKref and the envelope signal Sev detected by the envelope signal creating unit 200. In detail, the frequency counter unit 300 may acquire the frequency of the envelope signal Sev by counting the number of pulses of the reference clock CLKref for a period of the envelope signal Sev. The frequency of the envelope signal Sev has the same value as the frequency offset of the real time clock CLKrtc.

In detail, referring to FIG. 2, the frequency counter unit 300 may include a rising edge detector 310, a third counter 320, and a calculator 330. The rising edge detector 310 may detect periodic rising edges of the envelope signal Sev inputted thereto. The rising edges may be inputted to a reset terminal Rst of the third counter 320. The third counter 320 may create a first clock number N by counting the reference clock CLKref for the time between any one of the detected rising edges and the next rising edge. The calculator 330 may calculate the frequency of the envelope signal Sev by using the first clock number N.

A first counter 500 may count a second clock number Nref for a predetermined time by receiving the reference clock CLKref that may be inputted from the outside. Further, a second counter 510 may count a third clock number Nrtc for a predetermined time by receiving the real time clock CLKrtc created from the crystal oscillator.

An offset sign determining unit 400 receives the frequency of the envelope signal Sev acquired by the frequency counter unit 300, that is, the frequency offset of Δf of the real time clock CLKrtc and receives the second clock number Nref counted by the first counter 500 and the third clock number Nrtc counted by the second counter 510. The sign of the frequency offset value of the real time clock CLKrtc may be determined by comparing the respective clock numbers. Therefore, an accurate frequency offset Δf of the real time clock may be detected.

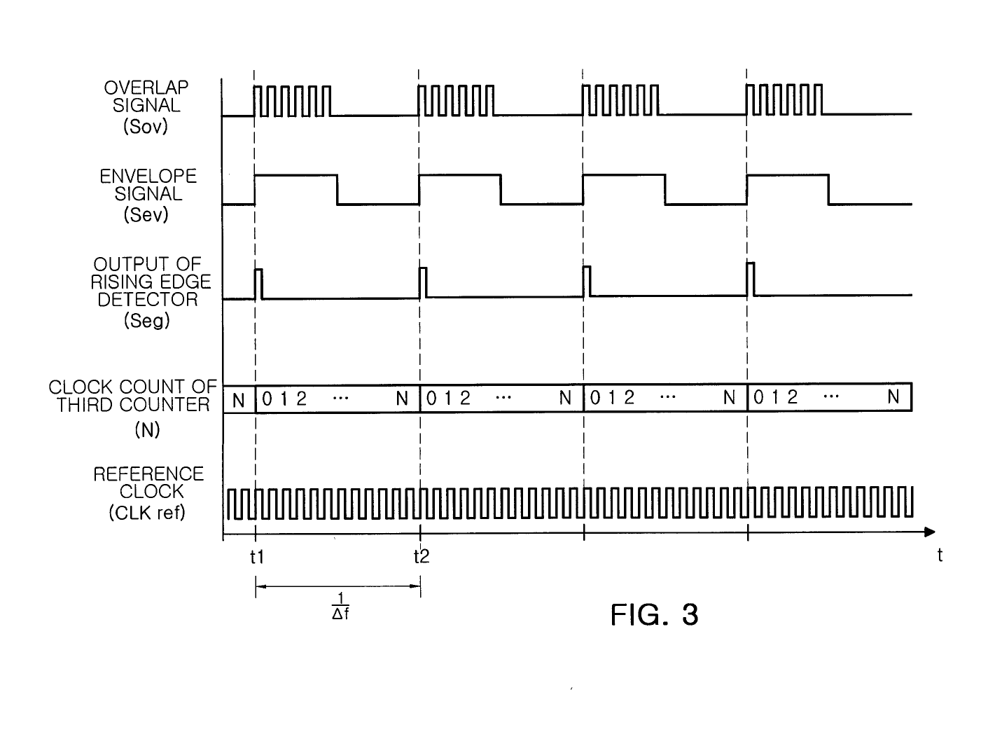

FIG. 3 is a timing chart illustrating signals and operations of respective units in the apparatus for detecting a real time clock frequency offset according to an embodiment of the present invention.

Referring to FIG. 3, the overlap signal Sov, the envelope signal Sev, an output waveform Seg of the rising edge detector 310, and a reference clock count in the third counter 320, and the reference clock CLKref are shown. The number from 0 to n in this graph showing the reference clock count in the third counter 320 represent counting the first clock number N for the time from one rising edge to the next rising edge in the rising edge detector 310.

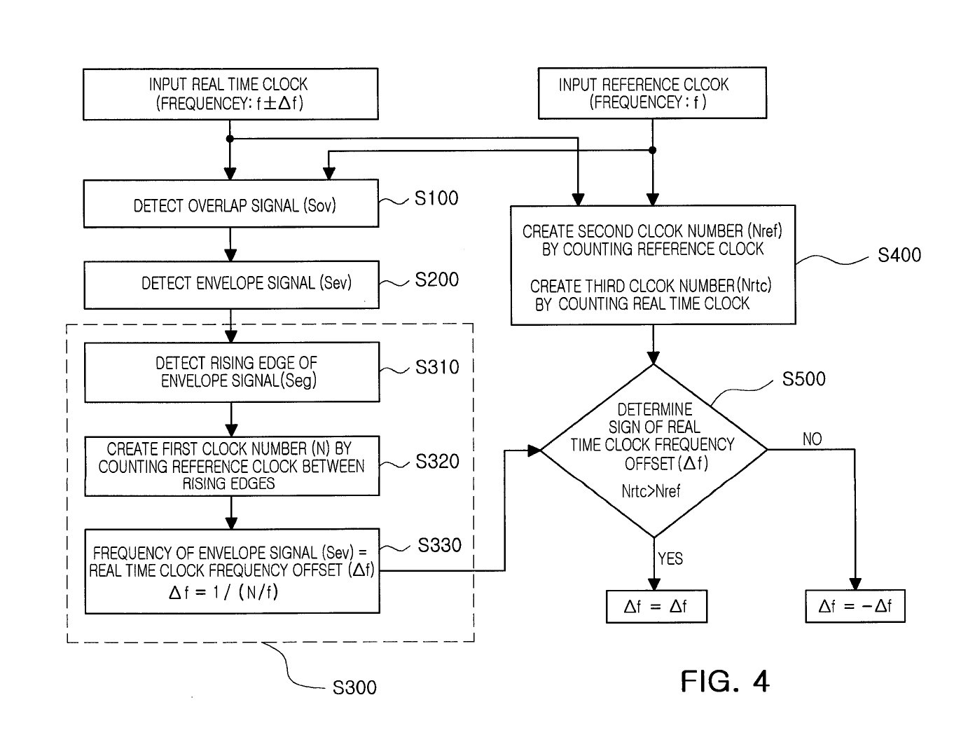

FIG. 4 is a flowchart illustrating respective processes of a method for detecting a real time clock frequency offset according to an embodiment of the present invention.

Referring to FIG. 4, a method for detecting a real time clock frequency offset according to an embodiment of the present invention may be applied to the apparatus for detecting a real time clock frequency offset which is illustrated in FIGS. 1 and 2. FIG. 4 shows in operation S100, detecting the overlap signal Soy having the overlap information of the reference clock CLKref and the real time clock CLKrtc and in operation S200, detecting the envelope signal Sev from the overlap signal Sov.

Further, An operation (S300) of calculating the frequency of the envelope signal Sev by using the frequency of the reference clock and the first clock number N created by counting the reference clock for a period of the envelope signal Sev includes detecting the rising edges of the envelope signal Sev (S310), creating the first clock number N by counting the reference clock between one rising edge to the next rising edge (S320), and calculating the frequency of the envelope signal Sev from the first clock number N (S330).

Further, an operation (S400) of counting the reference clock CLKref and the real time clock CLKrtc and an operation (S500) of determining the sign of the frequency offset of the real time clock CLKrtc by comparing the second clock number Nref and the third clock number Nrtc are sequentially shown in FIG. 4.

The operations and effects of the present invention are described hereafter in detail with reference to the accompanying drawings.

The apparatus for detecting a real time clock frequency offset according to an embodiment of the present invention is described with reference to FIGS. 1 to 3.

In FIG. 1, the inputs of the overlap detecting unit 100 are the real time clock CLKrtc generated from the crystal oscillator in a system or apparatus that uses the real time clock and the reference clock CLKref generated from a signal generator outside the system or apparatus. For example, the reference clock CLKref may be a clock having a frequency of 32,768 HZ. In this case, the real time clock CLKrtc may be a clock signal having a frequency error in the range of several to several tens of ppm from 32,768 HZ, that is, the frequency offset of the real time clock.

The overlap detecting unit 100 detects the overlap signal Sov formed of the overlapping portion of the reference clock CLKref and the real time clock CLKrtc overlap. More specifically, the reference clock CLKref and the real time clock CLKrtc are pulse trains having different frequencies in which low states and high states are periodically repeated and the overlap detecting unit 100 creates the overlap signal Sov having a high level in a time period where the high states of the two clocks are overlapped. In detail, referring to FIG. 2, the overlap detector 100 may be an AND gate that performs the AND-operation by using the reference clock CLKref and the real time clock CLKrtc as inputs.

The envelope signal creating unit 200 may receive the overlap signal Sov and detect the envelope thereof to create the envelope signal Sev. Referring to FIG. 3, it can be seen that the envelope of the overlap signal Sov detected by the overlap detecting unit 100 is a signal having a predetermined period. That is, the envelope of the overlap signal Sov calculated by overlapping the reference clock CLKref and the real time clock CLKrtc, which are periodic signals having different frequencies is a periodic signal, and the envelope signal Sev is acquired from the envelope.

The frequency counter unit 300 may calculate the frequency of the envelope signal Sev, that is, the frequency offset Δf of the real time clock, by receiving the reference clock CLKref and the envelope signal Sev detected by the envelope signal creating unit 200.

In detail, referring to FIG. 2, the frequency counter unit 300 includes the rising edge detector 310, the third counter 320, and the calculator 330. The rising edge detector 310 receives the envelope signal Sev and creates the signal Seg that falls after a short continuous time from the rising edge of the envelope signal Sev. Since the envelope signal Sev is a periodic signal, the output signal Seg of the rising edge detector 310 also has a periodicity. Referring to FIG. 3, the waveform of the output signal Seg of the rising edge detector 310 created in the process described above can be seen. Further, it can be seen that a period of the envelope signal Sev is the same as the time period from one rising edge to the next rising edge of the rising edge detector 310.

The third counter 200 receives the output signal Seg of the rising edge detector 310 through the reset terminal Rst thereof and creates the first clock number N by counting the reference clock CLKref for one period of the envelope signal Sev while receiving the reference clock CLKref. In detail, referring to FIG. 3, the third counter 320 is reset at the first rising edge of the output signal Seg of the rising edge detector 310 and counts the reference clock CLKref for the time period from the first rising edge to the next rising edge. Here, the first clock number N is created by counting the reference clock CLKref in the time period between the rising edges of the rising edge detector 310. However, since the period of the envelope signal Sev is the same as the period of the output signal Seg of the rising edge detector 310, counting the reference clock CLKref in the time period between the rising edges is the same as counting the reference clock CLKref for one period of the envelope signal Sev.

The calculator 330 calculates the frequency of the envelope signal Sev, that is, the real time clock frequency offset, by using the first clock number N. In more detail, since the period of the reference clock CLKref can be confirmed, it is possible to determine the period of the envelope signal Sev by multiplying the period of the reference clock CLKref by the first clock number N. It is possible to acquire the frequency of the envelope signal Sev by inverting the period of the envelope signal Sev. The frequency of the envelope signal Sev, which is acquired as described above, is the same as the real time clock frequency offset Δf, and as a result, the output of the calculator 330 is the real time clock frequency offset Δf.

The calculation is expressed by the following Formula:

$$Δ f = \frac{1}{( N / f )}$$

where Δf is the real time clock frequency offset, N is the first clock number, which is the clock number of the reference clock CLKref for one period of the envelope signal Sev calculated by the third counter 320, and f is the frequency of the reference clock CLKref.

The first counter 500 receives the reference clock CLKref generated from a signal generator outside a system or apparatus that uses a real time clock and counts the received reference clock for a predetermined time to create the second clock number Nref. Further, the second counter 510 creates the third clock number Nrtc by receiving the real time clock generated from a crystal oscillator in a system or apparatus which uses a real time clock and counting the real time clock for a time equally set to the counting time of the first counter 500.

The offset sign determining unit 400 determines an accurate real time clock frequency offset by receiving the real time clock frequency offset, which is the output from the frequency counter unit 300, and the outputs from the first counter 500 and second counter 510, and determining the sign Δf of the real time clock frequency offset.

More specifically, it is possible to confirm that which of the frequency of the reference clock CLKref and the frequency of the real time clock CLKrtc is larger, by comparing the second clock number Nret created by the first counter 500 with the third clock number Nrtc created by the second counter 510. For example, when the second clock number Nref counted by the first counter 500 is larger than the third clock number Nrtc counted by the second counter 510, it means that the frequency of the reference clock CLKref is larger than the frequency of the real time clock CLKrtc, such that the real time clock frequency offset has a minus (−) sign.

Referring to FIG. 4, the method for detecting a real time clock frequency offset according to an embodiment of the present invention includes detecting the overlap signal Sov having the overlap information of the reference clock CLKref and the real time clock CLKrtc (S100), detecting the envelope signal Sev from the overlap signal Sov (S200), calculating the frequency of the envelope signal Sev by counting the number of the reference clock CLKref for one period of the envelope signal Sev (S300), counting the reference clock CLKref and the real time clock CLKrtc (S400), and determining the sign of the frequency offset Δf of the real time clock by comparing the second clock number Nref and the third clock number Nrtc (S500).

Further, it can be seen that the calculating of the frequency of the envelope signal Sev by using the first clock number N created by counting the reference clock CLKref for one period of the envelope signal Sev (S300) includes detecting the rising edges of the envelope signal Sev (S310), creating the first clock number N by counting the reference clock CLKref between one rising edge and the next rising edge (S320), and calculating the frequency of the envelope signal Sev by using the frequency of the reference clock CLKref and the first clock number N (S330).

The detailed descriptions for explaining the processes are the same as that in the case of FIGS. 1 to 3 and thus, are not provided.

As described above, according to the present invention, it is possible to automatically detect an accurate real time clock frequency offset, without using expensive equipment such as a frequency comparator or the like. Further, since an accurate real time clock frequency offset may be provided during the correcting of the real time clock, necessity of using an expensive crystal oscillator is decreased and manufacturing costs can be reduced.

While the present invention has been shown and described in connection with the exemplary embodiments, it will be apparent to those skilled in the art that modifications and variations can be made without departing from the spirit and scope of the invention as defined by the appended claims.

What is claimed is:

1. An apparatus for detecting a real time clock frequency offset, the apparatus comprising:
an overlap detecting unit detecting an overlap signal having overlap information of a predetermined reference clock and a predetermined real time clock;
an envelope signal creating unit creating an envelope signal having envelope information of the overlap signal; and
a frequency counter unit calculating a frequency of the envelope signal that is a frequency offset of the real time clock, by using a first clock number created by counting the reference clock for one period of the envelope signal and a frequency of the reference clock.

2. The apparatus of claim 1, further comprising:
a first counter creating a second clock number by counting the reference clock for a predetermined time;
a second counter creating a third clock number by counting the real time clock for a predetermined time; and
an offset sign determining unit determining a sign of the frequency offset of the real time clock by comparing the second clock number with the third clock number.

3. The apparatus of claim 1, wherein the frequency counter unit includes:
a rising edge detector detecting rising edges of the envelope signal;
a third counter creating the first clock number by counting the reference clock between one rising edge and the next rising edge of the envelope signal; and
a calculator calculating the frequency of the envelope signal that is the frequency offset of the real time clock, by using the first clock number and the frequency of the reference clock.

4. The apparatus of claim 3, wherein the third counter receives the rising edges through a reset terminal thereof.

5. The apparatus of claim 1, wherein the frequency offset of the real time clock is calculated by the following formula:
$$Δ f = \frac{1}{( N / f )}$$
where Δf is the frequency offset of the real time clock, N is the first clock number, and f is the frequency of the reference clock.

6. The apparatus of claim 3, wherein the frequency offset of the real time clock is calculated by the following formula:
$$Δ f = \frac{1}{( N / f )}$$
where Δf is the frequency offset of the real time clock, N is the first clock number, and f is the frequency of the reference clock.

7. The apparatus of claim 1, wherein the overlap detecting unit includes an AND gate performing an AND-operation on the reference clock and the real time clock.

8. A method for detecting a real time clock frequency offset, the method comprising:
detecting an overlap signal having overlap information of a predetermined reference clock and a predetermined real time clock;
creating an envelope signal having envelope information of the overlap signal; and
calculating a frequency of the envelope signal that is a frequency offset of the real time clock, by using a first clock number counting the reference clock for one period of the envelope signal and a frequency of the reference clock.

9. The method of claim 8, further comprising:
counting the reference clock and the real time clock for a predetermined time; and
determining a sign of the frequency offset of the real time clock by comparing a second clock number created by counting the reference clock with a third clock number created by counting the real time clock.

10. The method of claim 8, wherein the calculating of the frequency of the envelope signal includes:
detecting rising edges of the envelope signal;
creating the first clock number by counting the reference clock between one rising edge and the next rising edge of the envelope signal; and
calculating the frequency of the envelope signal that is the frequency offset of the real time clock, by using the first clock number and the frequency of the reference clock.

11. The method of claim 10, wherein the creating of the first clock number includes resetting the counting of the reference clock at the rising edge.

12. The method of claim 8, wherein the frequency offset of the real time clock is calculated by the following formula:
$$Δ f = \frac{1}{( N / f )}$$
where Δf is the frequency offset of the real time clock, N is the first clock number, and f is the frequency of the reference clock.

13. The method of claim 10, wherein the frequency offset of the real time clock is calculated by the following formula:
$$Δ f = \frac{1}{( N / f )}$$
where Δf is the frequency offset of the real time clock, N is the first clock number, and f is the frequency of the reference clock.

14. The method according to claim 8, wherein the detecting of the overlap signal includes performing an AND-operation on the reference clock and the real time clock.
